(19) United States
(12) Patent Application Publication
(10) Pub. No.: US 2010/0028109 A1
(43) Pub. Date: Feb. 4, 2010

(54) EDGE GRIP END EFFECTOR

(75) Inventor: Richard J. Kent, Newbury, NH (US)

Correspondence Address: John A. Fortkort;Fortkort & Houston P.C., Suite 500, 9442 N. Capital of Texas Hwy, Building 1, Austin, TX, 78759, US

(73) Assignee: Fabworx Solutions, Inc.

(21) Appl. No.: 12/508,729

(22) Filed: Jul. 24, 2009

Related U.S. Application Data
(60) Provisional application No. 61/137,416, filed on Jul. 30, 2008.
(60) Provisional application No. 61/118,755, filed on Dec. 1, 2008.

(51) Int. Cl. H01L 21/683; B25J 18/00; B25J 17/02; F16H 55/26

(52) U.S. Cl. 414/225.01; 414/941; 74/490.01; 74/490.06; 74/422; 901/25; 901/29; 901/27; 901/30

(57) ABSTRACT

A robot is provided which comprises a wafer blade (105) having a pocket (109) therein for receiving a semiconductor wafer, and a retractable protrusion (107) which is movable from a first position in which said protrusion prevents the removal of said wafer from said pocket, to a second position in which said protrusion permits the removal of said wafer from said pocket.

### CROSS-REFERENCE TO RELATED APPLICATIONS

The present application claims priority to U.S. Ser. No. 61/137,416, entitled “Edge Grip End Effector”, which was filed on Jul. 30, 2008, and which is incorporated herein by reference in its entirety; and to U.S. Ser. No. 61/118,755, entitled “Edge Grip End Effector”, which was filed on Dec. 1, 2008, and which is incorporated herein by reference in its entirety.

### FIELD OF THE DISCLOSURE

The present disclosure relates generally to robots, and more particularly to robots equipped with mechanisms for securing a wafer within an end effector.

### BACKGROUND OF THE DISCLOSURE

The use of robots is widespread in the semiconductor industry, due to their ability to process a large number of semiconductor wafers through many different processing technologies, and to perform repetitive tasks quickly and accurately. The use of robots is especially advantageous in portions of semiconductor fabrication lines where human handling of semiconductor wafers is inefficient or undesirable. For example, many semiconductor fabrication processes, such as etching, deposition, and passivation, occur in reaction chambers having sealed environments. The use of robots allows these environments to be carefully maintained in order to minimize the likelihood of contamination and to optimize processing conditions.

Modern semiconductor processing systems include cluster tools that integrate a number of process chambers together in order to perform several sequential processing steps without removing the substrate from the highly controlled processing environment. These chambers may include, for example, degas chambers, substrate pre-conditioning chambers, cool-down chambers, transfer chambers, chemical vapor deposition chambers, physical vapor deposition chambers, and etch chambers. The combination of chambers in a cluster tool, as well as the operating conditions and parameters under which those chambers are run, are selected to fabricate specific structures using a specific process recipe and process flow.

Once the cluster tool has been set up with a desired set of chambers and auxiliary equipment for performing certain process steps, the cluster tool will typically process a large number of substrates by continuously passing them, one by one, through a series of chambers or process steps. The process recipes and sequences will typically be programmed into a microprocessor controller that will direct, control and monitor the processing of each substrate through the cluster tool. Once an entire cassette of wafers has been successfully processed through the cluster tool, the cassette may be passed to yet another cluster tool or stand alone tool, such as a chemical mechanical polisher, for further processing.

One example of a known fabrication system of the type described above is the cluster tool 101 disclosed in U.S. Pat. No. 6,222,337 (Kroeker et al.), and reproduced in FIGS. 1-2 herein. The magnetically coupled robots 103, 153 disclosed therein are equipped with upper 105 and lower 107 robotic arms having a frog-leg type construction that are adapted to provide both radial and rotational movement of the robot blade 109 within a fixed plane. The radial and rotational movements can be coordinated or combined to allow for pickup, transfer and delivery of substrates from one location within the cluster tool to another location. For example, the robotic arm may be used to move substrates from one processing chamber to an adjacent chamber.

FIG. 1 is a schematic diagram of the integrated cluster tool 101 of Kroeker et al. Wafers or other substrates 102 are introduced into, and withdrawn from, the cluster tool 101 through a cassette loadlock 111. A robot 103 having a blade 109 is located within a chamber 113 of the cluster tool 101 and is adapted to transfer the substrates from one process chamber to another. These process chambers may include, for example, a cassette loadlock 115, a degas wafer orientation chamber 117, a preclean chamber 119, a PVD TiN chamber 121 and a cooldown chamber 123. The robot blade 109 is illustrated in the retracted position in which it can rotate freely within the chamber 113.

A second robot 153 is located in transfer chamber 163, and is adapted to transfer substrates between various chambers which may include, for example, a cool-down chamber 165, a pre-clean chamber 167, a CVD Al chamber 169 and a PVD AlCu processing chamber 171. The specific configuration of chambers illustrated in FIG. 1 is designed to provide an integrated processing system capable of both CVD and PVD processes in a single cluster tool. A microprocessor controller 171 is provided to control the fabricating process sequence, conditions within the cluster tool, and the operation of the robots 103, 153.

Robots of the type depicted in FIGS. 1-2 above are utilized, for example, in the ENDURA® and CENTURA® 200 nm/300 nm platforms sold by Applied Materials (Santa Clara, Calif.). As seen in FIG. 2, these robots 103 include a central hub 131, a pair of upper arms 105, and a pair of lower arms 107. The lower arms 107 are rotatingly attached to the hub 131 and are driven by servo drives housed within the hub 103.

### SUMMARY OF THE DISCLOSURE

In one aspect, a robot is provided which comprises a wafer blade having a pocket therein for receiving a semiconductor wafer; and at least one retractable protrusion which is movable from a first position in which said protrusion prevents the removal of said wafer from said pocket, to a second position in which said protrusion permits the removal of said wafer from said pocket.

In another aspect, an end effector is provided which comprises a wafer blade having a pocket therein for receiving a semiconductor wafer; and a retractable protrusion which is movable from a first position in which it secures said wafer in said pocket, to a second position in which said wafer is removable from said pocket.

In a further aspect, a robot is provided which comprises (a) a robotic arm which extends along a path including first, second and third points, wherein said arm is in a relatively retracted position at said first point and is in a relatively extended position at said third point, and wherein said second point is disposed between said first and third points; (b) an end effector which is attached to said arm; and (c) a mechanical actuator disposed in said end effector, said actuator assuming a first state when said robotic arm is at said first point, and assuming a second state when said robotic arm is at said second point.

In still another aspect, a robot is provided which comprises (a) a robotic arm which extends along a path including first, second and third points; (b) an end effector which is attached to said arm; and (c) a mechanical actuator disposed in said end effector, said actuator assuming a first state when said robotic arm is at said first point, and assuming a second state when said robotic arm is at said second point; wherein said arm is in a more retracted position when it is at said first point compared to when it is at said third point, wherein said second point is disposed between said first and third points.

In a further aspect, a robot is provided which comprises (a) a robotic arm which is extendible to assume at least first, second and third positions, wherein said arm is more extended when it is in the second position relative to the first position, and wherein said arm is more extended when it is in the third position relative to the second position; (b) an end effector which is attached to said arm; and (c) a mechanical actuator disposed in said end effector, said actuator assuming a first state when said robotic arm is in said first position, and assuming a second state when said robotic arm is in said second position.

In yet another aspect, a robot is provided which comprises (a) a hub; (b) a robotic arm which is extendible from said hub to assume at least first, second and third positions, wherein said arm is more extended when it is in the second position relative to the first position, and wherein said arm is more extended when it is in the third position relative to the second position; (c) an end effector which is attached to said arm; and (d) a mechanical actuator disposed in said end effector, said actuator assuming a first state when said robotic arm is in said first position, and assuming a second state when said robotic arm is in said second position.

### BRIEF DESCRIPTION OF THE DRAWINGS

For a more complete understanding of the present disclosure and the advantages thereof, reference is now made to the following description taken in conjunction with the accompanying drawings in which like reference numerals indicate like features and wherein:

FIG. 1 is an illustration of a prior art cluster tool.

FIG. 2 is an illustration of a prior art robot.

FIG. 3 is an illustration of a first particular, non-limiting embodiment of a wrist assembly made in accordance with the teachings herein, showing the upper slide in a disengaged position and the wafer hold finger in an engaged position.

FIG. 4 is an illustration of the wrist assembly of FIG. 3, showing the upper slide in an engaged position, and the wafer hold finger in a disengaged position.

FIG. 5 is an illustration of the wrist assembly of FIG. 3, in which the wrist assembly has been partially disassembled to show the details of the rack and pinion system.

FIG. 6 is an illustration of the upper rack and slide of the wrist assembly of FIG. 3, with the cover removed and the wafer hold finger in a retracted position.

FIG. 7 is an illustration of the upper rack and slide of the wrist assembly of FIG. 3, with the cover removed and the wafer hold finger in an engaged position.

FIG. 8 is an illustration of the wrist assembly of FIG. 3 showing the location of the pinion.

FIG. 9 is an illustration of the wrist plate of the wrist assembly of FIG. 3.

FIG. 10 is an illustration of the components of the rack and pinion system of the wrist assembly of FIG. 3.

FIG. 11 is an illustration of a wafer blade and wrist assembly incorporating the wrist assembly of FIG. 3, and showing the wafer hold finger in a retracted position (in this position, the plunger is forced inward by the forearm making contact where my thumb is).

FIG. 12 is an illustration of a wafer blade and wrist assembly incorporating the wrist assembly of FIG. 3, and showing the wafer hold finger in an engaged position (in this position, plunger is in the outward direction, making contact with the wafer).

FIG. 13 is an illustration of the wafer blade from the assembly of FIG. 12.

FIG. 14 is a magnified view of REGION 14 of FIG. 13.

FIG. 15 is a top view of the upper rack and slide of the wrist assembly of FIG. 3.

FIG. 16 is a bottom view of the upper rack and slide of the wrist assembly of FIG. 3.

FIG. 17 is an illustration of some of the components of a rack and pinion system utilized in some of the devices described herein.

FIG. 18 is an illustration of a wrist assembly of a robotic arm made in accordance with the teachings herein, shown with a cover plate removed and with the arms in a retracted position.

FIG. 19 is an illustration of a wrist assembly of a robotic arm made in accordance with the teachings herein, shown with a cover plate removed and with the arms in an extended position.

FIG. 20 is a bottom view of FIG. 18.

### DETAILED DESCRIPTION

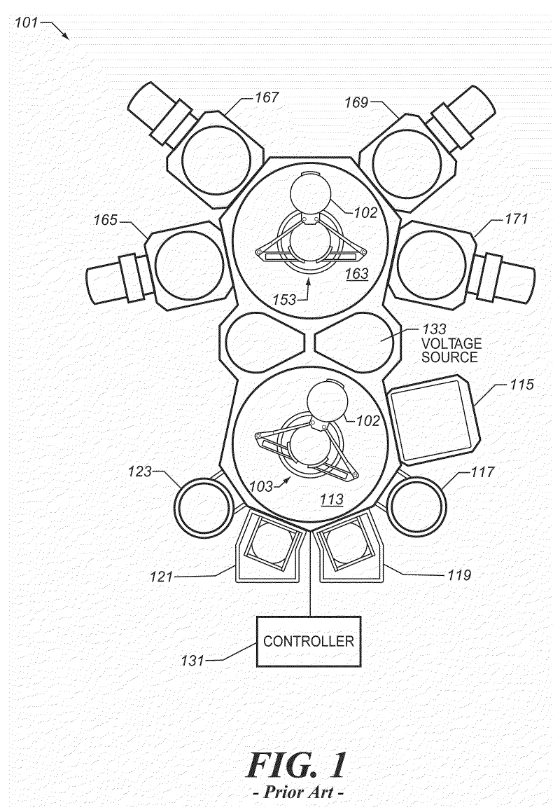

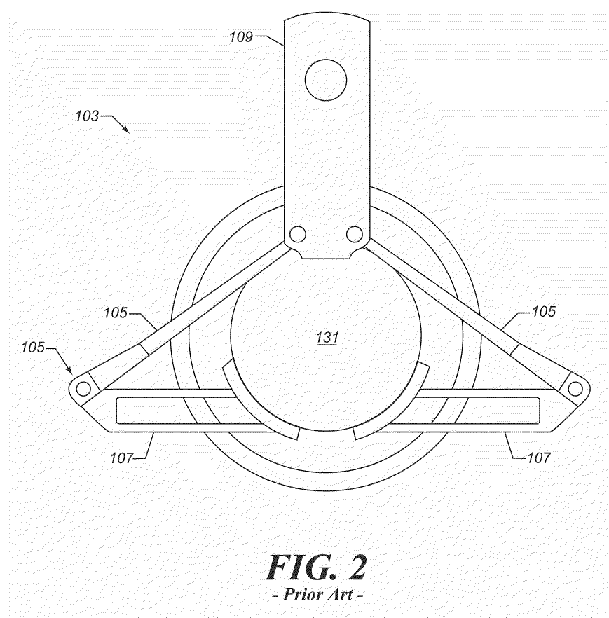

While the robots depicted in FIGS. 1-2 have some advantageous features, they also suffer from some infirmities. In particular, as semiconductor processing speeds have increased, it has become increasingly difficult for robots of this type to maintain the semiconductor wafer in a proper position within the pocket of the wafer blade.

It has now been found that the foregoing problem may be addressed through the provision of a robot (or an end effector thereof) which is equipped with a wafer holding means for preventing a wafer from moving inside of a wafer blade pocket while the robot is moving at higher speeds. Preferably, the wafer holding means can be deactivated when the robot is moving at slower speeds, or when removal of the wafer blade from the wafer blade pocket is desired.

In one preferred embodiment, for example, the wafer holding means is in the form of a finger which engages a wafer disposed in the wafer blade pocket while the wafer blade is moving at higher speeds. In this particular embodiment, the finger disengages the wafer when, and only when, the arms of the robot are extended a predefined distance k, where k is typically chosen to be sufficiently large such that, when k is reached, the wafer is nearing its target and/or the wafer blade is moving at a slower speed. The wafer blade is preferably fitted with a plurality of elastomeric pads and/or a plurality of elastomeric posts so that, at such slower speeds, the wafer is prevented from moving within the wafer blade pocket even when the finger is disengaged.

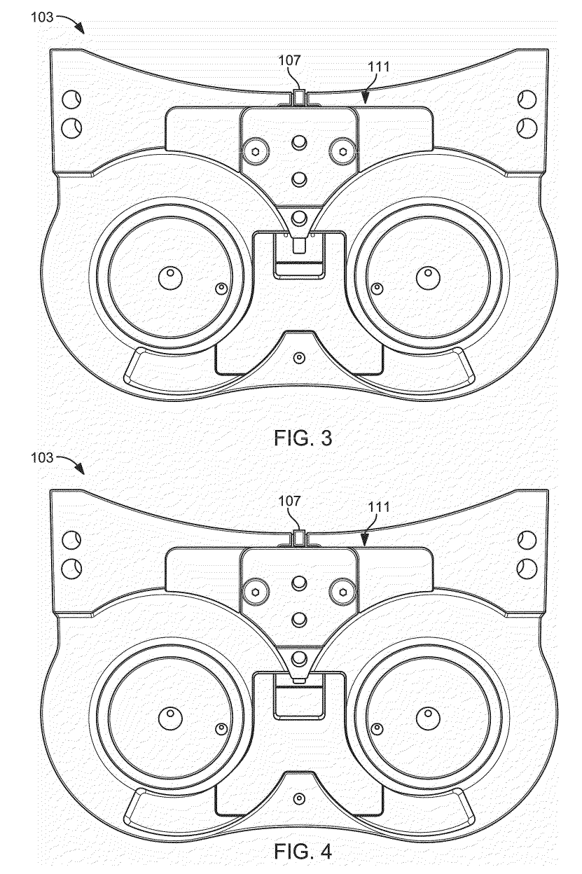

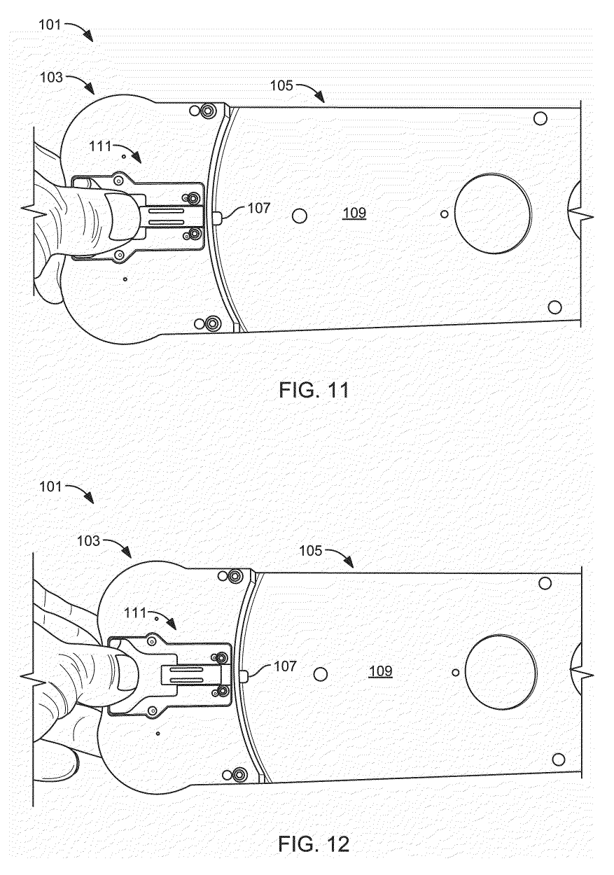

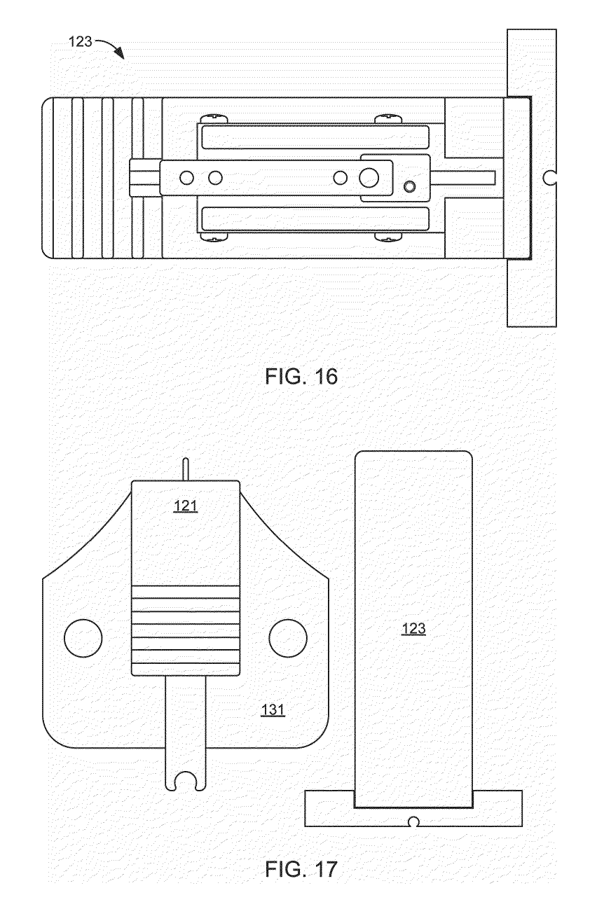

The devices and methodologies disclosed herein may be further understood with reference to the first particular, non-limiting embodiment, depicted in FIGS. 3-20, of a robot and its associated end effector made in accordance with the teachings herein. As seen in FIGS. 11-12, an end effector assembly 101 is provided which includes a wrist assembly 103 and a wafer blade 105. The wrist assembly 103 is equipped with a protrusion 107 which, in the present embodiment, is essentially cylindrical in shape. The protrusion 107, which may comprise a metal and/or elastomeric material, extends into a circular wafer pocket 109 or depression provided in the surface of the wafer blade 105.

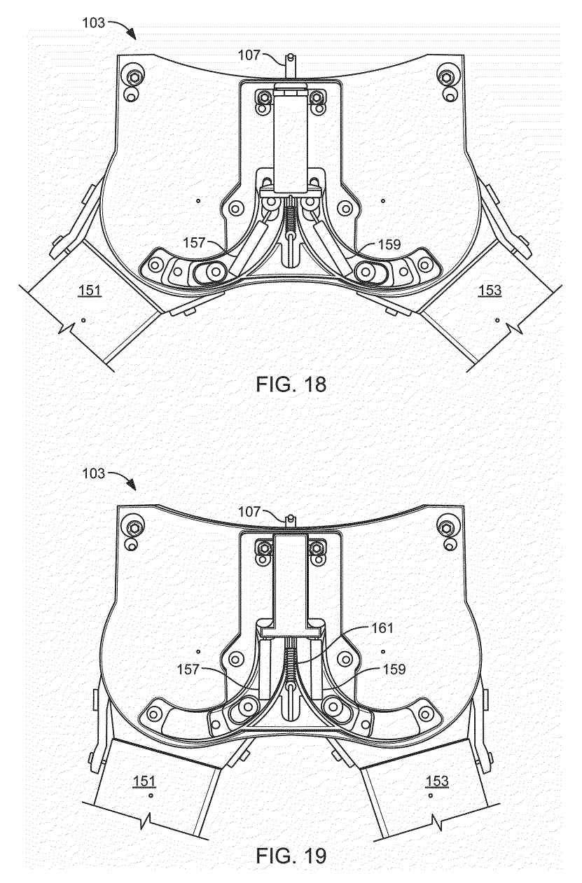

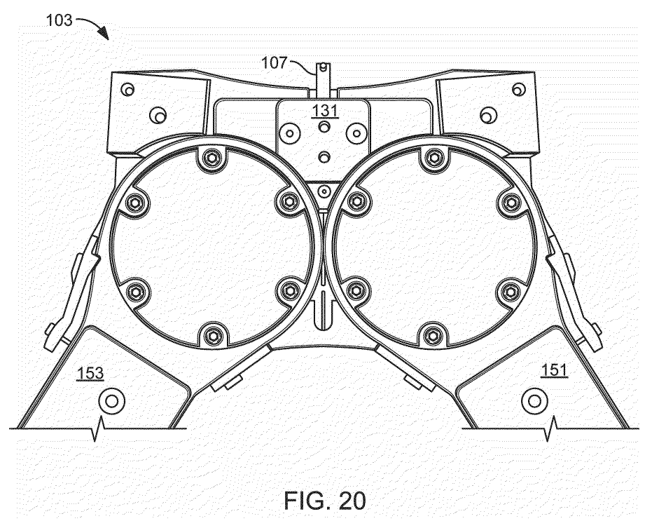

The protrusion 107 in the particular embodiment depicted is driven by a rack-and-pinion system 111 which is housed within the wrist assembly 103. The rack-and-pinion system 111 moves the protrusion 107 between an extended position, as shown in FIGS. 11 and 18, and a retracted position, as shown in FIGS. 12 and 20. Although the difference in the amount by which the protrusion 107 moves in going from a retracted position to an extended position is typically small, the force exerted upon the wafer when the protrusion 107 is in the extended position is sufficiently high to secure the wafer within the wafer pocket 109 when the wafer blade 105 is moving at high speeds. As explained in greater detail below, in a preferred embodiment, the robotic arm is mechanically adapted such that the finger engages the wafer when the wafer blade is moving at higher speeds, and disengages the wafer as the arm extends and nears its target.

The wrist assembly 103 (with cover plate removed) is shown in greater detail in FIGS. 3, 4 and 18-20. As seen therein, the rack-and-pinion system 111 serves to move the protrusion 107 from a first position in which the protrusion 107 prevents the removal of a wafer (not shown) from the wafer blade pocket 109 (see FIGS. 12, 18 and 20), to a second position in which the protrusion 107 permits the removal of the wafer from the pocket 109 (see FIGS. 11 and 19). Preferably, this is accomplished by moving the protrusion 107 axially along a diameter of the wafer pocket 109 so that the protrusion 107 engages a wafer disposed in the pocket 109 when the protrusion 107 is in the first position, and disengages the wafer when it is moved into the second position.

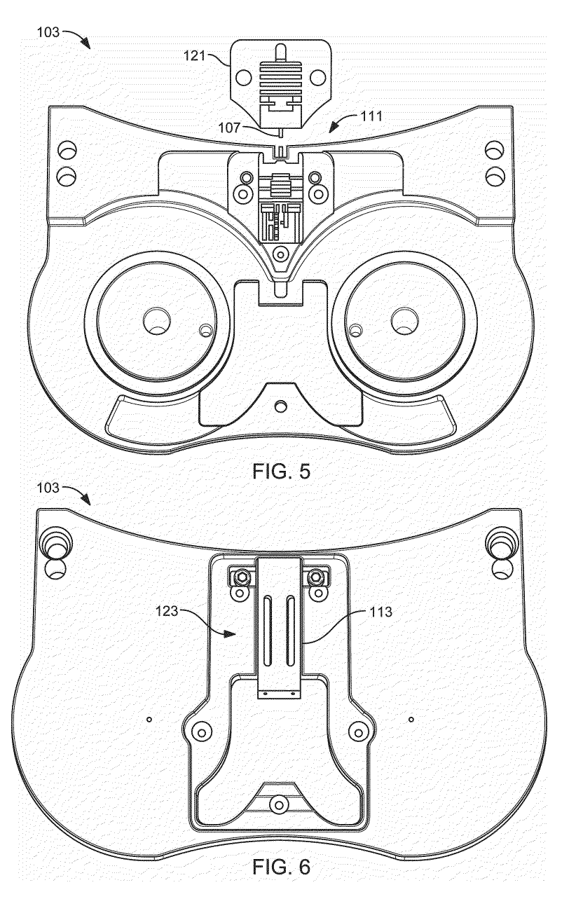

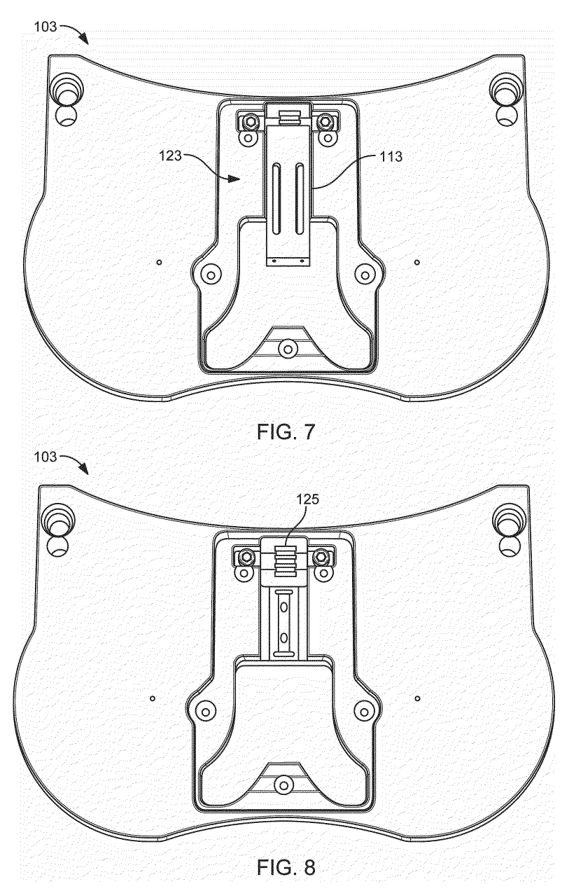

FIGS. 5-10 show the details of the rack-and-pinion system 111. With reference to FIG. 5, the wrist assembly 103 is shown with the lower rack 121 and cover plate 131 removed to reveal the details thereof, including the protrusion 107. FIG. 6 shows the upper rack 123 (with the cover removed) with the protrusion 107 in the retracted position. FIG. 7 shows the upper rack 123 (with the cover removed) with the protrusion 107 in the extended position.

In one possible configuration of a robot made in accordance with the teachings herein, the end effector assembly 101 of FIG. 3 is mounted on first 151 and second 153 robotic arms as shown in FIGS. 18-20. In operation, as the robotic arms 151, 153 extend, plates 157 and 159 rotate in a counterclockwise manner to engage the upper rack 123 of the rack-and-pinion system 111. Since the upper rack 123 is in communication with the lower rack 121 by way of a pinion 125 (see FIG. 10), the upper 123 and lower 121 racks move in opposite directions. Hence, since the lower rack has protrusion 107 mounted thereon, as the plates 157, 159 press against the upper rack 123, the protrusion 107 retreats. Conversely, as the arms 151, 153 retract, the plates 157, 159 are withdrawn from the upper rack 123 (see FIGS. 6-7). Since an internal spring 161 is attached to the upper rack 123, as the plates 157 and 159 are withdrawn from the upper rack 123, the upper rack 123 pulls back, thus causing the protrusion 107 to extend into the wafer pocket 109. The spring 161 is preferably equipped with one or more set screws which allow the tension of the spring to be adjusted.

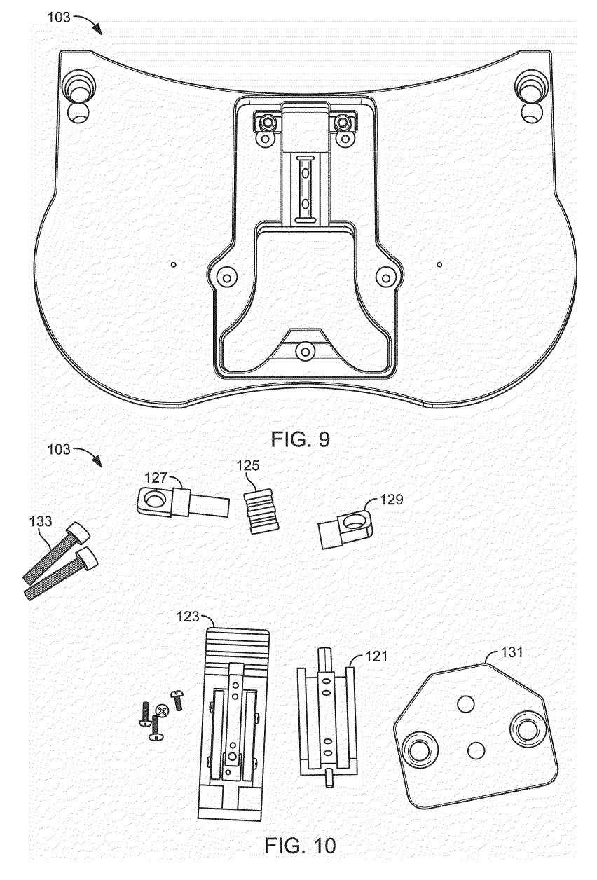

FIGS. 8-10 illustrate further details of the design of the wrist assembly. Thus, FIG. 8 shows a bottom view of the wrist assembly 103 with the lower 121 and upper 123 racks removed to reveal the pinion gear 125. FIG. 9 shows the wrist assembly 103 alone. FIG. 10 shows some of the components of the wrist assembly 103. These include the pinion gear 125, the right axle 127, the left axle 129, the upper rack 123, the lower rack 121, the cover plate 131, and a plurality of fasteners 133.

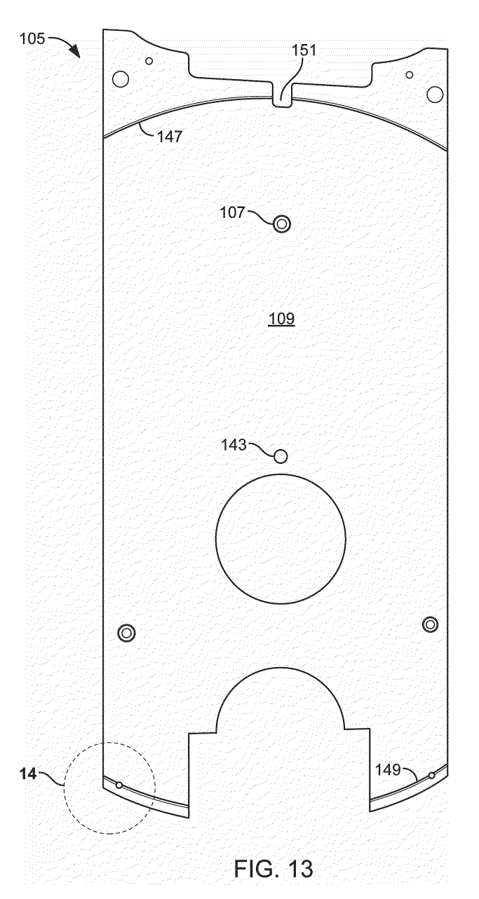

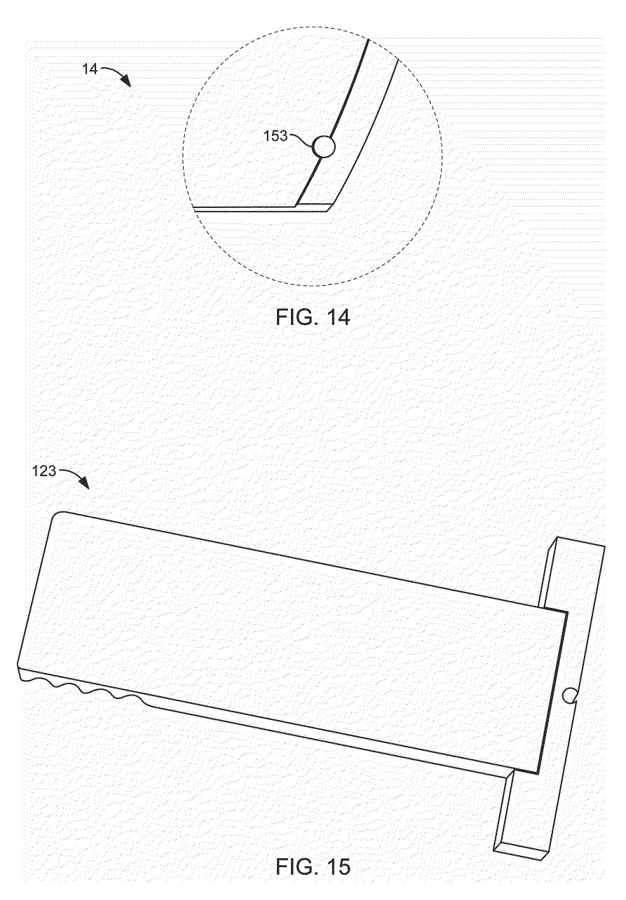

FIGS. 13-14 depict the wafer blade 105 in greater detail. The wafer blade 105 in the particular embodiment depicted is machined from 6061 aluminum which is hard-coated with aluminum oxide. The aluminum oxide minimizes particle formation in the event of wafer-to-metal contact. The wafer blade 105 is equipped with a (preferably circular) pocket 109 on the surface thereof which is adapted to hold a complimentary-shaped wafer (not shown). The circular pocket 109 is provided with high temperature elastomeric O-rings 143 which support a wafer above the surface of the wafer blade 105 to ensure a clean, particle-free environment. The O-rings 143 may comprise an elastomeric material, such as a perfluoroelastomer. The combination of the O-rings 143, the wafer pocket 109 and elastomeric posts 173 (described below) permits the protrusion 107 to disengage the wafer as the arms 151, 153 approach the end of their extension, without risking movement of the wafer at the slower speeds encountered there.

The wafer pocket 109 is defined by opposing sidewalls 147 and 149. Sidewall 147 is equipped with a notch 151 which permits the protrusion 107 (see FIGS. 3-4) to extend therethrough. Sidewall 149 (shown in greater detail in FIG. 14) is equipped with two elastomeric posts 173 which are generally rod-shaped and which protrude about 0.012 to about 0.015 inches into the pocket 141. Protrusion 107 (see FIGS. 3-4) is of a similar construction and also protrudes about 0.012 to about 0.015 inches into the pocket 141.

The use of elastomeric posts 173 in combination with protrusion 107 to grip the wafer allows the protrusion 107 to press against the wafer with greater force than would be the case if the wafer were being pressed against a rigid surface. Moreover, this force is adjustable by virtue of spring 161. This arrangement maintains the wafer in the pocket while the protrusion is extended and prevents damage to the wafer which might otherwise result from the clamping force. The wafer is also engaged and disengaged much more slowly than pneumatic clamps of the type used in the prior art, thus preventing damage to the wafer from “knocking”. As a further benefit, the wafer is gripped from at least three points along its edges. Since the wafer typically has the greatest momentum along an axis parallel to its major surfaces when the wafer blade is in motion, this arrangement minimizes the force required to maintain the wafer in the wafer blade pocket.

One advantage of the foregoing embodiment is that the wrist assembly can be configured so that the point at which the finger 107 engages the wafer can be adjusted over a wide range. This allows the robot to accommodate a wide variety of tool settings. In a cluster tool, where the robotic arm may have to interact with several chambers, this point may be set in reference to the closest chamber (that is, the chamber requiring the least extension of the robotic arm). By contrast, conventional robots equipped with actuating mechanisms typically have fixed set points, and thus cannot accommodate a need for changes in the set point.

It will be appreciated that the devices and methodologies disclosed herein may be utilized for other purposes besides maintaining wafers within a wafer pocket. For example, in many retrofit applications involving existing robots, it is desirable to add functionality to the robot. However, such modifications are often constrained by available assets. For example, it may be challenging to retrofit a robotic arm with a pneumatic tool if the robotic arm lacks wiring or other means to control the tool. However, the approach described herein may be utilized to mechanically activate the tool when the robotic arm is extended a certain distance (or range of distances). For example, a rack and pinion system of the type described above may be used in such a robot as a mechanical actuator to move the tool between a first and second state which may be, for example, an “on” state and an “off” state.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A robot, comprising:
a wafer blade having a pocket therein for receiving a semiconductor wafer; and
at least one retractable protrusion which is movable from a first position in which said protrusion prevents the removal of said wafer from said pocket, to a second position in which said protrusion permits the removal of said wafer from said pocket.

2. The robot of claim 1, wherein said at least one protrusion is extended when it is in the first position, and is retracted when it is in the second position.

3. The robot of claim 1, wherein said robot further comprises at least one forearm which is connected to said wafer blade by way of a wrist assembly.

4. The robot of claim 3, wherein said at least one protrusion extends from said wrist assembly.

5. The robot of claim 4, wherein said at least one protrusion is centrally located on said wrist assembly.

6. The robot of claim 4, wherein said pocket is adapted to hold a circular wafer, and wherein said at least one protrusion extends along a diameter of said circle.

7. The robot of claim 1, wherein said at least one protrusion is manipulated by way of a rack-and-pinion system.

8. The robot of claim 4, wherein said at least one protrusion is manipulated by way of a rack-and-pinion system disposed in said wrist assembly.

9. The robot of claim 2, wherein said robot further comprises at least one forearm which is connected to said wafer blade by way of a wrist assembly, wherein said at least one protrusion is adapted to assume the first position when said arm is extended, and wherein said at least one protrusion is adapted to assume the second position when said arm is retracted.

10. The robot of claim 1, wherein said at least one protrusion is essentially cylindrical in shape.

11. The robot of claim 1, wherein said at least one protrusion is in said first position when the arm is retracted, and wherein said at least one protrusion is in said second position when the arm is extended.

12. The robot of claim 11, wherein said arm passes through a set point as it extends from a retracted position to a fully extended position, wherein the set point is reached before the arm assumes a fully extended position, and wherein said at least one retractable protrusion remains in said second position when the arm is disposed between the set point and the fully extended position.

13. The robot of claim 12, wherein said set point is adjustable.

14. The robot of claim 1, wherein said at least one protrusion includes first and second spaced apart protrusions.

15. The robot of claim 14, wherein said pocket is bounded on one end by an arcuate wall, and wherein said first and second protrusions extend from said arcuate wall.

16. The robot of claim 14, wherein said pocket is equipped with a plurality of elastomeric pads adapted to support a wafer thereon.

17. The robot of claim 1, wherein said at least one protrusion applies a force of at least 0.5 N to a wafer disposed in said pocket.

18. The robot of claim 1, wherein said at least one protrusion applies a force of at least 0.7 N to a wafer disposed in said pocket.

19. The robot of claim 1, wherein the force applied by the protrusion to a wafer disposed in said pocket is adjustable.

20. The robot of claim 19, wherein the movement of the protrusion is controlled by a rack and pinion system.

21. The robot of claim 19, wherein the force applied by the protrusion is controlled at least partially by a spring.

22. The robot of claim 19, further comprising at least one robotic arm, wherein said rack and pinion system is adapted to extend said protrusion into said pocket as said at least one robotic arm retracts, and is further adapted to retract said protrusion from said pocket as said at least one robotic arm extends.

23. The robot of claim 1, wherein said protrusion comprises a perfluoroelastomer.

24. An end effector, comprising:
a wafer blade having a pocket therein for receiving a semiconductor wafer; and
a retractable protrusion which is movable from a first position in which it secures said wafer in said pocket, to a second position in which said wafer is removable from said pocket.

25. The end effector of claim 24 wherein said protrusion is extended when it is in the first position, and is retracted when it is in the second position.

26. A robot, comprising:
a robotic arm which extends along a path including first, second and third points, wherein said arm is in a relatively retracted position at said first point and is in a relatively extended position at said third point, and wherein said second point is disposed between said first and third points;
an end effector which is attached to said arm; and
a mechanical actuator disposed in said end effector, said actuator assuming a first state when said robotic arm is at said first point, and assuming a second state when said robotic arm is at said second point.

27. The robot of claim 26, wherein said actuator is a rack and pinion system.

28. The robot of claim 27, wherein said end effector includes a wafer blade having a pocket defined therein and a protrusion which extends into said pocket, wherein said rack and pinion system moves said protrusion from a first position when said arm is at said first point to a second position when said arm is at said second point, and wherein said protrusion extends into said pocket more when it is in said first position than when it is in said second position.

29. A robot, comprising:
a robotic arm which extends along a path including first, second and third points;
an end effector which is attached to said arm; and
a mechanical actuator disposed in said end effector, said actuator assuming a first state when said robotic arm is at said first point, and assuming a second state when said robotic arm is at said second point;
wherein said arm is in a more retracted position when it is at said first point compared to when it is at said third point, wherein said second point is disposed between said first and third points.

30. A robot, comprising:
a robotic arm which is extendible to assume at least first, second and third positions, wherein said arm is more extended when it is in the second position relative to the first position, and wherein said arm is more extended when it is in the third position relative to the second position;
an end effector which is attached to said arm; and
a mechanical actuator disposed in said end effector, said actuator assuming a first state when said robotic arm is in said first position, and assuming a second state when said robotic arm is in said second position.

31. The robot of claim 30, wherein said actuator is also in said second state when said robotic arm is in said third position.

32. The robot of claim 30, wherein said actuator remains in said second state while said robotic arm moves from said second position to said third position.

33. The robot of claim 30, wherein said actuator is a mechanical actuator.

34. The robot of claim 33, wherein said actuator includes a rack and pinion system.

35. The robot of claim 34, wherein said end effector includes a wafer blade having a pocket defined therein and a protrusion which extends into said pocket, wherein said rack and pinion system moves said protrusion from a first point when said arm is in said first position to a second point when said arm is in said second position, and wherein said protrusion extends into said pocket more when it is at said first point than when it is at said second point.

36. The robot of claim 30 further comprising a pneumatic device, wherein said actuator activates the pneumatic device when it is in said first state, and deactivates the pneumatic device when it is in the second state.

37. The robot of claim 30 further comprising an electronic device, wherein said actuator activates the electronic device when it is in said first state, and deactivates the electronic device when it is in the second state.

38. The robot of claim 37, wherein said actuator is a switch.

39. The robot of claim 30, further comprising a hub; wherein the robotic arm is extendible from said hub to assume said at least first, second and third positions.

40. A robot, comprising:
a hub;
a robotic arm which is extendible from said hub to assume at least first, second and third positions, wherein said arm is more extended when it is in the second position relative to the first position, and wherein said arm is more extended when it is in the third position relative to the second position;
an end effector which is attached to said arm; and
a mechanical actuator disposed in said end effector, said actuator assuming a first state when said robotic arm is in said first position, and assuming a second state when said robotic arm is in said second position.
